(19) United States
(12) Patent Application Publication
(10) Pub. No.: US 2026/0173620 A1
(43) Pub. Date: Jun. 18, 2026

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventors: Joo Hyeon LEE, Yongin-si (KR); Hyun Seok OH, Yongin-si (KR); Kang Woo LEE, Yongin-si (KR)

(21) Appl. No.: 19/331,376

(22) Filed: Sep. 17, 2025

(30) Foreign Application Priority Data
Dec. 13, 2024 (KR) 10-2024-0186045

(51) Int. Cl. H10H 29/80; H10H 29/01

(52) U.S. Cl. CPC H10H 29/842; H10H 29/034

(57) ABSTRACT

Provided are the display device, a method of manufacturing the display device, and an electronic device including the displays device. The display device includes a display panel including a light-emitting element; and a coating layer disposed on the display panel and including nanoparticles, which are greater than 5 wt % to less than 15 wt % of a total weight of the coating layer.

This application claims priority to Korean Patent Application No. 10-2024-0186045, filed on Dec. 13, 2024, and all the benefits accruing therefrom under 35 U.S.C. § 119, the content of which in its entirety is herein incorporated by reference.

### BACKGROUND

### 1. Field

The disclosure relates to display device. Specifically, the disclosure relates to a display device, a method of manufacturing the same and an electronic device including the same.

### 2. Description of the Related Art

Recently, as interest in an information display has been increasing, research and development on a mask assembly manufacturing a display device have been continuously conducted.

The above description is only for the purpose of facilitating an understanding of the background art of the technical ideas of the present disclosure, and thus it cannot be understood as content corresponding to the prior art known to those skilled in the art of the present disclosure.

### SUMMARY

An aspect provides a display device with improved reliability.

Another aspect provides a method of manufacturing the display device.

Another aspect provides an electronic device including the display device.

Aspects of the disclosure are not limited to the aspect described above, and other technical aspects which are not described may be clearly understood by those skilled in the art from the description below.

According to embodiments of the disclosure, a display device includes a display panel including a light-emitting element; and a coating layer disposed on the display panel and including nanoparticles, which are greater than 5 weight percents (wt %) to less than 15 wt % of a total weight of the coating layer.

In an embodiment, the coating layer may include a base layer in which the nanoparticles are dispersed.

In an embodiment, the base layer may include an optically clear resin (OCR).

In an embodiment, the base layer may include at least one of an acrylic polymer, a urethane polymer, or a silicone polymer.

In an embodiment, each of the nanoparticles may include silica.

In an embodiment, each of the nanoparticles may include at least one of acrylic, styrene, or polymethyl methacrylate (PMMA).

In an embodiment, an elongation of the coating layer may be equal to or greater than 150% and less than 161%.

In an embodiment, a modulus of the coating layer at 0.1 Hz of stress may be greater than 0.47 to less than 3.5 megapascal (MPa).

In an embodiment, an adhesive force of the coating layer at room temperature may be equal to or greater than 800 gram-force per inch (gf/inch) and less than 994 gf/inch.

In an embodiment, a haze of the coating layer may be greater than 0.48% to less than 1.46%.

In an embodiment, the nanoparticles may be surface-coated.

According to embodiments of the disclosure, a method of manufacturing a display device, the method includes forming a display panel including a light-emitting element; and forming a coating layer including nanoparticles, which are greater than 5 wt % to less than 15 wt % of a total weight of the coating layer, on the display panel.

In an embodiment, the forming of the coating layer may include dispersing the nanoparticles in a resin solution; applying the resin solution onto the display panel to form an uncured base layer; and curing the uncured base layer to form a base layer.

In an embodiment, the uncured base layer may be cured by at least one of an ultraviolet curing method or a low-temperature thermosetting method.

In an embodiment, the base layer may include an optically clear resin (OCR).

In an embodiment, each of the nanoparticles may include silica.

In an embodiment, each of the nanoparticles may include at least one of acrylic, styrene, or polymethyl methacrylate (PMMA).

According to embodiments of the disclosure, an electronic device includes a processor; and a display device configured to display an image according to control of the processor, the display device includes a display panel including a light-emitting element; and a coating layer disposed on the display panel and including nanoparticles, which are greater than 5 wt % to less than 15 wt % of a total weight of the coating layer.

In an embodiment, the coating layer may have a recovery rate greater 90.2% than to less than 95.1%.

In an embodiment, a modulus of the coating layer at 1000 Hz of stress may be greater than 21 to less than 410 MPa.

Specific details of other embodiments are included in the detailed description and drawings.

According to the embodiment described above, since the coating layer includes nanoparticles, the coating layer may have a shear thickening property. Accordingly, the impact resistance of the coating layer may be improved. In addition, since the coating layer includes nanoparticles, which are greater than 5 wt % to less than 15 wt % of nanoparticles a total weight of the coating layer, the coating layer may not significantly deteriorate in foldability, light transmittance, and adhesion while securing impact resistance, and thus may secure foldability, light transmittance, and adhesion at the same time as impact resistance. Accordingly, while the coating layer prevents damage to the display panel, the reliability of the display device may be improved by securing the foldability and the light transmittance of the display device. In addition, since the coating layer has adhesive force, a separate adhesive layer may not be required, so that the structure of the display device may become simple, and the thickness of the display device may be reduced.

An effect according to embodiments is not limited to the contents exemplified above, and more various effects are included in the present specification.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating an embodiment of a display device.

FIG. 2 is a block diagram illustrating an embodiment of any one of the sub-pixels of FIG. 1.

FIG. 3 is a perspective view illustrating an embodiment of the display device of FIG. 1.

FIG. 4 is a view illustrating a folding state of the display device illustrated in FIG. 3.

FIG. 5 is a cross-sectional view illustrating an embodiment taken along line I-I′ of FIG. 3.

FIG. 6 is a cross-sectional view illustrating another embodiment taken along line I-I′ of FIG. 3.

FIG. 7 is a cross-sectional view illustrating an embodiment of the display panel of FIG. 5.

FIG. 8 is a cross-sectional view illustrating another embodiment of the display panel of FIG. 5.

FIG. 9 is an enlarged cross-sectional view illustrating only the coating layer and the display panel of FIG. 5.

FIG. 10 is a cross-sectional view illustrating a state when the coating layer and the display panel of FIG. 9 are subjected to external stress.

FIG. 11 is a graph illustrating a result of performing a pen drop test on a coating layer according to a comparative example and an embodiment.

FIGS. 12 to 17 are views illustrating a method of manufacturing a display device according to an embodiment of the present disclosure.

FIG. 18 is a block diagram of an electronic device according to an embodiment.

FIG. 19 is a schematic diagram of an electronic device according to various embodiments.

### DETAILED DESCRIPTION

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Similar reference numerals are used for similar components in describing each drawing. In the accompanying drawings, the dimensions of the structures are shown enlarged from the actual dimensions for the sake of clarity of the disclosure. Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. A case where a portion of a layer, a layer, an area, a plate, or the like is referred to as being “on” another portion, it includes not only a case where the portion is “directly on” another portion, but also a case where there is further another portion between the portion and another portion. In the present specification, in case that a portion of a layer, a layer, an area, a plate, or the like is formed on another portion, a forming direction is not limited to an upper direction but includes forming the portion on a side surface or in a lower direction. On the contrary, in case that a portion of a layer, a layer, an area, a plate, or the like is formed “under” another portion, this includes not only a case where the portion is “directly beneath” another portion but also a case where there is further another portion between the portion and another portion.

Hereinafter, preferred embodiments of the disclosure and others necessary for those skilled in the art to understand the disclosure will be described in detail with reference to the accompanying drawings. In the following description, the singular expressions include plural expressions unless the context clearly dictates otherwise.

“About” or “substantially the same” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5% or 2% of the stated value.

Throughout the disclosure, the expression “at least one of a, b or c” indicates only a, only b, only c, both a and b, both a and c, both b and c, all of a, b, and c, or variations thereof.

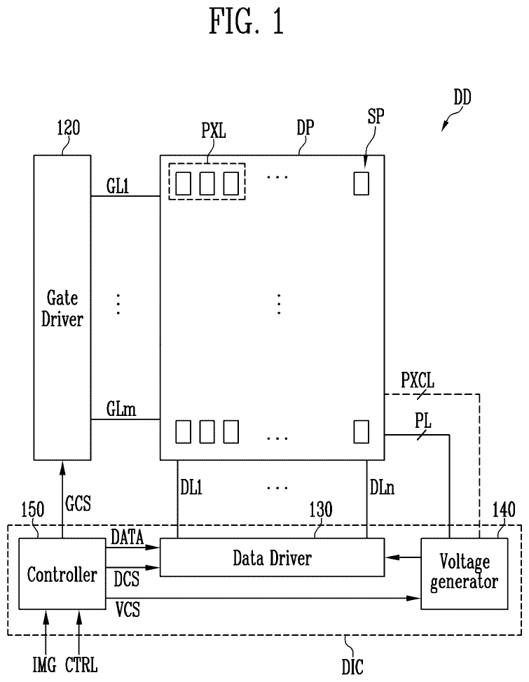

FIG. 1 is a block diagram illustrating an embodiment of a display device.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red, green, blue, cyan, magenta, yellow, or the like.

Two or more sub-pixels of the sub-pixels SP may constitute one pixel PXL. For example, the pixel PXL may include three sub-pixels as shown in FIG. 1. As such, the pixel PXL may emit light of various colors and various luminances according to a combination of light emitted from sub-pixels included therein.

The gate driver 120 may be connected to the sub-pixels SP arranged in a row direction through the first to m-th gate lines GL1 to GLm. The gate driver 120 may output gate signals to the first to m-th gate lines GL1 to GLm in response to the gate control signal GCS. In embodiments, the gate control signal GCS may include a start signal indicating the start of each frame, a horizontal synchronization signal, and the like.

The gate driver 120 may be disposed on one side of the display panel DP. However, embodiments are not limited thereto. For example, the gate driver 120 may be divided into two or more drivers that are physically and/or logically divided, and such drivers may be disposed on one side of the display panel DP and the other side of the display Panel DP opposite to the one side. As such, the gate driver 120 may be disposed around the display panel DP in various forms according to embodiments.

The data driver 130 may be connected to the sub-pixels SP arranged in a column direction through the first to n-th data lines DL1 to DLn. The data driver 130 may receive the image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may use the received voltages to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Accordingly, the sub-pixels SP may generate light corresponding to the data signals, and the display panel DP may display an image.

In embodiments, gate driver 120 and data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD, such as the gate driver 120, the data driver 130, and the controller 150. The voltage generator 140 may generate a plurality of voltages by receiving an input voltage from outside the display device DD and regulating the received voltage.

The voltage generator 140 may generate a first power supply voltage and a second power supply voltage. The generated first and second power supply voltages may be provided to the sub-pixels SP through power supply lines PL. In other embodiments, at least one of the first and second power supply voltages may be provided from outside the display device DD.

In addition, the voltage generator 140 may provide various voltages and/or signals. For example, the voltage generator 140 may provide one or more initialization voltages applied to sub-pixels SP. For example, in a sensing operation for sensing electrical characteristics of transistors and/or light-emitting elements of the sub-pixels SP, a predetermined reference voltage may be applied to the first to n-th data lines DL1 to DLn, and the voltage generator 140 may generate and transmit the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide pixel control signals to sub-pixels SP via pixel control lines PXCL. Although the pixel control lines PXCL are shown in FIG. 1 as being connected between the voltage generator 140 and the display panel DP, embodiments are not limited thereto. For example, the pixel control lines PXCL may be connected between the gate driver 120 and the display panel DP. In this case, the pixel control signals may be transmitted from the voltage generator 140 to the pixel control lines PXCL via the gate driver 120.

The controller 150 may control various operations of the display device DD. The controller 150 may receive an input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP and output the image data DATA. In embodiments, the controller 150 may output the image data DATA by aligning the input image data IMG to fit the sub-pixels SP in rows.

Two or more components of the data driver 130, the voltage generator 140, and the controller 150 may be mounted in one integrated circuit. As shown in FIG. 1, the data driver 130, the voltage generator 140, and the controller 150 may be included in a driver integrated circuit (DIC). In this case, the data driver 130, the voltage generator 140, and the controller 150 may be functionally distinct components within one driver integrated circuit (DIC). In other embodiments, at least one of the data driver 130, the voltage generator 140, or the controller 150 may be provided as a component separate from the driver integrated circuit (DIC).

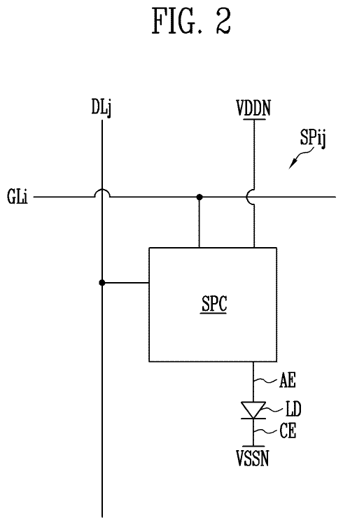

FIG. 2 is a block diagram illustrating an embodiment of any one of the sub-pixels of FIG. 1. In FIG. 2, among the sub-pixels SP in FIG. 1, a sub-pixel SPij arranged in an i-th row (i is an integer greater than or equal to 1 and less than or equal to m) and a j-th column (j is an integer greater than or equal to 1, and less than or equivalent to n) is exemplarily shown.

Referring to FIG. 2, the sub-pixel SPij may include a sub-pixel circuit SPC and a light-emitting element LD.

The light-emitting element LD may be connected between the first power voltage node VDDN and the second power voltage node VSSN. The first power supply voltage node VDDN may be connected to one of the power supply lines PL of FIG. 1 to receive the first power supply voltage. The second power supply voltage node VSSN may be connected to the other one of the power supply lines PL of FIG. 1 to receive the second power supply voltage. The first power supply voltage may have a higher voltage level than the second power supply voltage.

The light-emitting element LD may be connected between an anode electrode AE and a cathode electrode CE. The anode electrode AE may be connected to the first power supply voltage node VDDN through the sub-pixel circuit SPC. For example, the anode electrode AE may be connected to the first power supply voltage node VDDN through one or more transistors included in the sub-pixel circuit SPC. The cathode electrode CE may be connected to the second power supply voltage node VSSN. The light-emitting element LD may be configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to the gate signal received via the i-th gate line GLi, the sub-pixel circuit SPC may control the light-emitting element LD to emit light in accordance with the data signal received via the j-th data line DLj. In embodiments, the sub-pixel circuit SPC may be further connected to the pixel control lines PXCL of FIG. 1. In this case, the sub-pixel circuit SPC may further control the light-emitting element LD in response to pixel control signals received through the pixel control lines PXCL.

For such operations, the sub-pixel circuit SPC may include circuit elements, e.g., transistors and one or more capacitors.

The transistors of the sub-pixel circuit SPC may include P-type transistors and/or N-type transistors. In embodiments, transistors of the sub-pixel circuit SPC may include a metal oxide silicon field effect transistor (MOSFET). In embodiments, transistors of the sub-pixel circuit SPC may include an amorphous silicon semiconductor, a monocrystalline silicon, a polycrystalline silicon semiconductor, an oxide semiconductor, or the like.

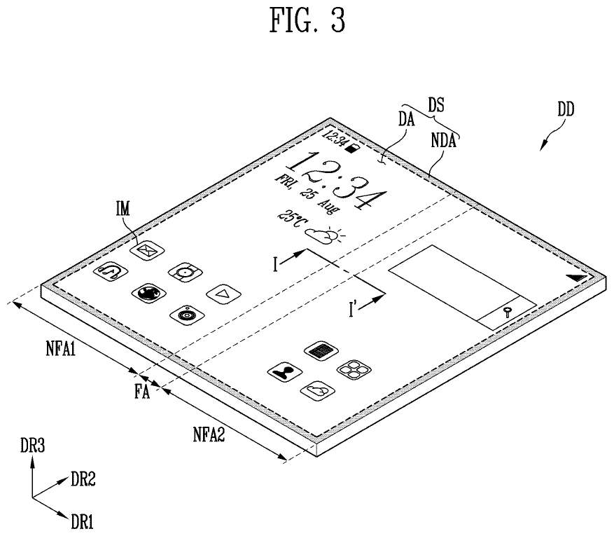

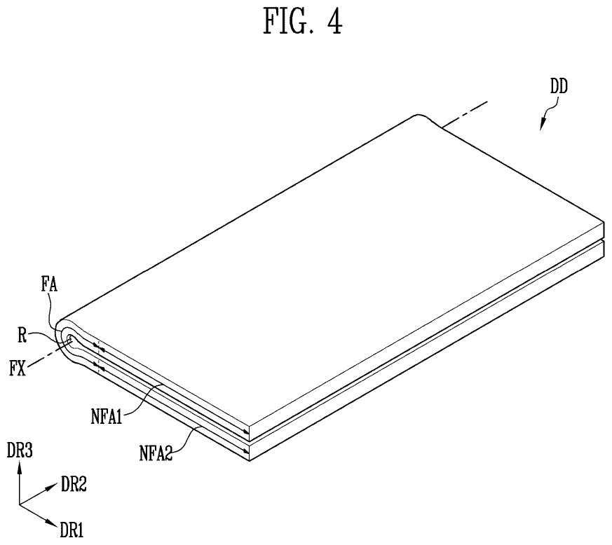

FIG. 3 is a perspective view illustrating an embodiment of the display device of FIG. 1. FIG. 4 is a view illustrating a folding state of the display device illustrated in FIG. 3.

Referring to FIG. 3, the display device DD according to an embodiment of the present disclosure may have a rectangular shape having short sides extending in a first direction DR1 and long sides extending in a second direction DR2 intersecting the first direction DR1. However, the shape of the display device DD is not limited thereto, positions of the short sides and the long sides of the display device DD may be interchanged, and the display device DD may have various shapes such as a circle and a polygon. The display device DD may be a flexible display device.

Hereinafter, a direction substantially perpendicularly intersecting a plane defined by the first direction DR1 and the second direction DR2 may be defined as a third direction DR3. In addition, in the present specification, “when viewed in a plan view” may be defined as a state viewed in the third direction DR3.

The display device DD may include a folding area FA and a plurality of non-folding areas NFA1 and NFA2 adjacent to the folding area FA. The non-folding areas NFA1 and NFA2 may include a first non-folding area NFA1 and a second non-folding area NFA2. The second non-folding area NFA2 may be spaced apart from the first non-folding area NFA1 in the first direction DR1. The folding area FA may be disposed between the first non-folding area NFA1 and the second non-folding area NFA2. The first non-folding area NFA1, the folding area FA, and the second non-folding area NFA2 may be arranged in the first direction DR1.

Exemplarily, one folding area FA and two non-folding areas NFA1 and NFA2 are shown, but the number of folding areas FA and non-folding area NFA1 and NFA2 is not limited thereto. For example, the display device DD may include more than two non-folding areas and a plurality of folding areas disposed between the non-folding areas.

A top surface of the display device DD may be defined as a display surface DS, and the display surface DS may have a plane defined by the first direction DR1 and the second direction DR2. Images IM generated by the display device DD may be provided to the user through the display surface DS.

The display surface DS may include a display area DA and a non-display area NDA around the display area DA. The display area DA may display an image, and the non-display area NDA may not display an image. The non-display area NDA may surround the display area DA and define an edge of the display device DD printed in a predetermined color.

Although not shown, the display device DD may include at least one sensor and at least one camera. The sensor may be a near-illuminance sensor, but the type of sensor is not limited thereto. The camera may take external images.

Referring to FIG. 4, the display device DD may be a folded (foldable) display device DD that is folded or unfolded. For example, the folding area FA may be bent with respect to the folding axis FX parallel to the second direction DR2, so that the display device DD may be folded. The folding axis FX may be defined as a long axis parallel to the long side of the display device DD. The folding area FA may be curved to have a radius of curvature R.

When the display device DD is folded, the first non-folding area NFA1 and the second non-folding area NFA2 may face each other, and the display device DD may be in-folded so that the display surface DS is not exposed to the outside. However, embodiments of the present disclosure are not limited thereto. For example, the display device DD may be out-folded such that the display surface DS is exposed to the outside around the folding axis FX.

The distance between the first and second non-folding areas NFA1 and NFA2 may be less than twice the radius of curvature R. In this case, the folding area FA may be folded into a dumbbell shape.

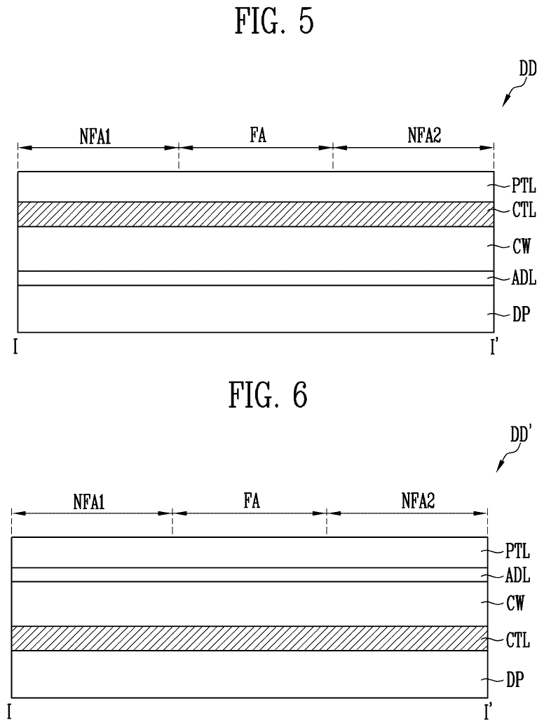

FIG. 5 is a cross-sectional view illustrating an embodiment taken along line I-I′ of FIG. 3. FIG. 6 is a cross-sectional view illustrating another embodiment taken along line I-I′ of FIG. 3.

Referring to FIG. 5, the display device DD may include the display panel DP, an adhesive layer ADL, a cover window CW, a coating layer CTL, and a protective layer PTL.

The cover window CW may be disposed on the display panel DP. The cover window CW may be attached to the display panel DP through the adhesive layer ADL. The adhesive layer ADL may include an optically clear adhesive (OCA).

The cover window CW may be configured to protect its lower layers. The cover window CW may include glass, but embodiments are not limited thereto. For example, the cover window CW may be an encapsulation glass configured to protect components disposed underneath the cover window CW. In other embodiments, the cover window CW may be omitted.

The coating layer CTL may be disposed on the cover window CW. The coating layer CTL may have an adhesive force and be directly attached to the cover window CW without the adhesive layer ADL. The coating layer CTL may also have shear thickening properties. Accordingly, the coating layer CTL may have excellent impact resistance and protect the lower cover window CW and the display panel DP from external impact. In addition, the coating layer CTL may have foldability with low modulus and be easily folded in the folding area FA.

The protective layer PTL may be disposed on the coating layer CTL. Since the coating layer CTL may have adhesion, the protective layer PTL may be directly attached to the coating layer CTL. The protective layer PTL may prevent damage to the cover window CW.

Referring to FIG. 6, the display device DD′ may include a display panel DP, an adhesive layer ADL, a cover window CW, a coating layer CTL, and a protective layer PTL.

The coating layer CTL may be disposed on the display panel DP. The coating layer CTL may have an adhesive force to be directly attached to the display panel DP without the adhesive layer ADL therebetween. The coating layer CTL may also have the shear thickening properties. Accordingly, the coating layer CTL may have excellent impact resistance and protect the lower display panel DP from external impact. In addition, the coating layer CTL may have foldability with low modulus and be easily folded in the folding area FA.

A cover window CW may be disposed on the coating layer CTL. Since the coating layer CTL has an adhesive force, the cover window CW may be directly attached to the coating layer CTL without the adhesive layer ADL.

A protective layer PTL may be disposed on the cover window CW. The protective layer PTL may be attached to the cover window CW through the adhesive layer ADL.

The present disclosure is not limited to the embodiments of FIGS. 5 and 6, and the display device DD, DD′ may further include other layers and members in addition to the display panel DP, the adhesive layer ADL, the cover window CW, the coating layer CTL, and the protective layer PTL, and the coating layer CTL may be disposed anywhere between the upper layers of the display panel DP. Hereinafter, the display device according to an embodiment of FIG. 5 will be described.

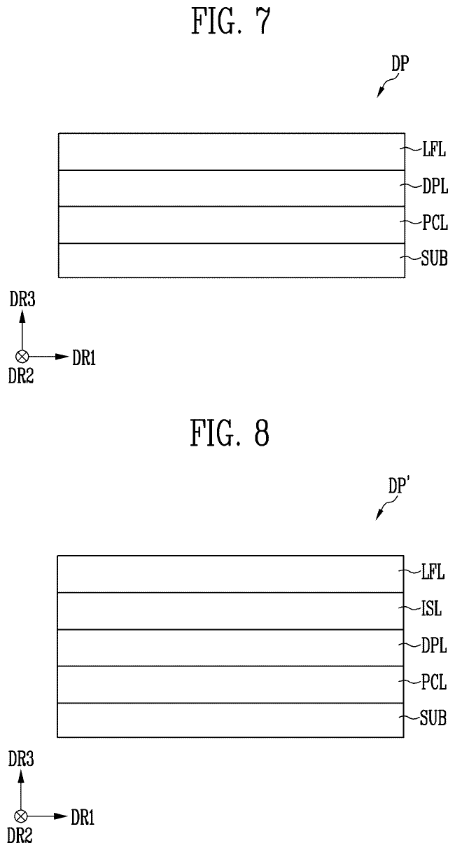

FIG. 7 is a cross-sectional view illustrating an embodiment of the display panel of FIG. 5.

Referring to FIG. 7, the display panel DP may include a substrate SUB, and a pixel circuit layer PCL, a display element layer DPL, and a light functional layer LFL sequentially stacked on the substrate SUB in a third direction DR3 intersecting the first and second directions DR1 and DR2.

The substrate SUB may be made of an insulating material such as glass or resin. For example, the substrate SUB may include a glass substrate. As another example, the substrate SUB may include a polyimide (PI) substrate. As another example, the substrate SUB may include a silicon wafer substrate formed using a semiconductor process.

In an embodiment, the substrate SUB may be made of a material that is flexible to allow bending or folding, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate. However, embodiments are not limited thereto.

The pixel circuit layer PCL may be disposed on the substrate SUB. The pixel circuit layer PCL may include insulating layers, semiconductor electrodes, and conductive electrodes disposed between the insulating layers. The conductive electrodes of the pixel circuit layer PCL may function as circuit elements, wirings, or the like.

The circuit elements of the pixel circuit layer PCL may include the sub-pixel circuit SPC (see FIG. 2) of each of the sub-pixels included in the pixel PXL. In other words, the circuit elements of the pixel circuit layer PCL may be provided with transistors and one or more capacitors of the sub-pixel circuit SPC.

The wirings of the pixel circuit layer PCL may include wirings connected to sub-pixels. The wirings of the pixel circuit layer PCL may include various signal lines and/or voltage lines necessary for driving the display element layer DPL.

The display element layer DPL may be disposed on the pixel circuit layer PCL. The display element layer DPL may include the light-emitting elements of sub-pixels.

The optical functional layer LFL may be disposed on the display element layer DPL. The light functional layer LFL may include light conversion patterns having color conversion particles and/or scattering particles. For example, the color-converting particles may include quantum dots. The quantum dots may change the wavelength (or color) of light emitted from the display element layer DPL. The light functional layer LFL may further include light scattering patterns having scattering particles. In an embodiment, the light conversion patterns and the light scattering patterns may be omitted.

The optical functional layer LFL may further include a color filter layer including color filters. The color filter may selectively transmit light of a particular wavelength (or color). In an embodiment, the color filter layer may be omitted.

FIG. 8 is a cross-sectional view illustrating another embodiment of the display panel of FIG. 5.

Referring to FIG. 8, the display panel DP′ may include a substrate SUB, a pixel circuit layer PCL, a display element layer DPL, an input sensing layer ISL, and an optical functional layer LFL. The substrate SUB, the pixel circuit layer PCL, the display element layer DPL, and the optical functional layer LFL are configured in the same manner as the substrate SUB, the pixel circuit layer PCL, the display element layer DPL, and the optical functional layer LFL described with reference to FIG. 4, respectively. Hereinafter, redundant descriptions will be omitted.

The input sensing layer ISL may sense a user input to an upper surface (or a display surface) of the display panel DP′. The input sensing layer ISL may include configurations suitable for sensing an external object such as a user's hand, pen, or the like. For example, the input sensing layer ISL may include touch electrodes.

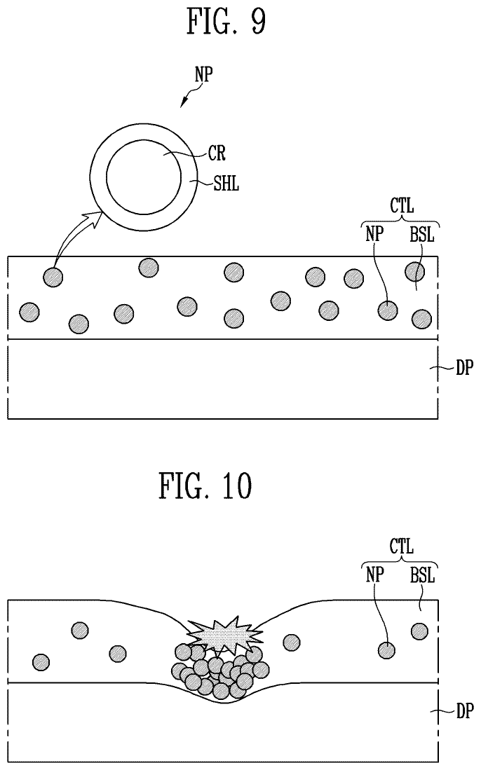

FIG. 9 is an enlarged cross-sectional view illustrating only the coating layer and the display panel of FIG. 5. FIG. 10 is a cross-sectional view illustrating a state when the coating layer and the display panel of FIG. 9 are subjected to external stress. In FIGS. 9 and 10, components other than the coating layer and the display panel are omitted for convenience of description.

Referring to FIGS. 9 and 10, the coating layer CTL may be disposed on the display panel DP. The coating layer CTL may include a base layer BSL and nanoparticles NP. The nanoparticles NP may be disposed to be dispersed in the base layer BSL.

The base layer BSL may include an optically clear resin (OCR). Specifically, the base layer BSL may include at least one of an acrylic polymer, a urethane polymer, or a silicone polymer.

In embodiments, an elongation of the coating layer CTL may be greater than or equal to about 150% in terms of shear strain applied to the folding area FA (see FIG. 5) based on an in-folding state. When the elongation of the coating layer CTL is less than about 150%, foldability in the folding area FA is not secured, and thus the display device DD may not be easily folded. In embodiments, an elongation of the coating layer CTL may be greater than or equal to 150% and less than 161% in terms of shear strain applied to the folding area FA (see FIG. 5) based on an in-folding state.

In embodiments, the room temperature modulus of the coating layer CTL in terms of buckling index may be about 1 MPa or less. When the modulus of the coating layer CTL is greater than about 1 MPa, as with the elongation, foldability in the folding area FA may not be secured, and thus the display device DD may not be easily folded. In embodiments, the modulus of the coating layer CTL at the room temperature and low stress (e.g., 0.1 Hz) in terms of buckling index may be greater than 0.47 MPa and equal to or less than about 1 MPa.

In embodiments, a room temperature adhesion of the coating layer CTL may be about 800 gf/inch or more. When the adhesive force of the coating layer CTL is less than about 800 gf/inch, the coating layer CTL may not adhere to the upper and lower layers (e.g., the cover window CW and the display panel DP of FIG. 5) and an additional adhesive layer may be required. In embodiments, an adhesive force of the coating layer CTL at a room temperature may be equal to or greater than 800 gf/inch and less than 994 gf/inch.

The nanoparticles NP may be included in the coating layer CTL in a ratio of greater than 5 wt % to less than 15 wt % with respect to a total weight of the coating layer. Since the nanoparticles NP are dispersed in the base layer BSL, the coating layer CTL may have the shear thickening property. The shear thickening property may be defined as a property in which when a part of the coating layer CTL is deformed according to a stress applied to the coating layer CTL, the modulus of the part of the deformed coating layer CTL increases. Accordingly, when an external impact is applied to the display device DD, the coating layer CTL having the shear thickening property absorbs energy due to the external impact, so that the display panel DP may be prevented from being damaged by the external impact. That is, as the coating layer CTL has the shear thickening property, the impact resistance of the coating layer CTL may be improved, and the display panel DP may be protected.

When the nanoparticles NP are included in the coating layer CTL in an amount of 5 wt % or less, the shear thickening property of the coating layer CTL may be weakened. Accordingly, since the impact resistance of the coating layer CTL is not secured, the coating layer CTL may not properly perform a role of protecting the display panel DP.

Conversely, when the nanoparticles NP are included in the coating layer CTL in an amount of 15 wt % or more, since the number of particles dispersed in the base layer BSL increases, the shear thickening property of the coating layer CTL may be enhanced, but the optical properties of the coating layer CTL may decrease and the adhesion of the coating layer CTL may be weakened. Accordingly, although the impact resistance of the coating layer CTL is improved, the light efficiency as the display device DD may not be secured, and the role as an adhesive member between the internal components of the display device DD may not be properly performed.

In embodiments, the nanoparticles NP may include silica, which is an inorganic material. In this case, the base layer BSL may include a silicon-based polymer. However, embodiments are not limited thereto.

In embodiments, the nanoparticles NP may include at least one of acrylic, styrene, or polymethyl methacrylate (PMMA), which is an organic material. However, embodiments are not limited thereto.

In embodiments, the nanoparticles NP may be surface coated. That is, the nanoparticles NP may be formed of a core CR and a shell SHL. The core CR may have a spherical shape, and the shell SHL may entirely cover the core CR. Since the nanoparticles NP are surface-coated, an interfacial adhesion between the nanoparticles NP and the base layer BSL may be improved, and the dispersibility of the nanoparticles NP may be improved.

In embodiments, the haze of the coating layer CTL may be less than about 1%. As used herein, the haze may be measured as a percentage of incident light scattered by more than 2.5 degrees through the coating layer. A light transmittance of the coating layer CTL may be about 90% or more. Since the haze of the coating layer CTL is less than about 1% and the light transmittance is about 90% or more, the reduction in the light transmittance of the display device DD due to the coating layer CTL may be prevented, and thus the light efficiency of the display device DD may be ensured. In embodiments, the haze of the coating layer CTL may be greater than 0.48% and less than about 1%.

Hereinafter, a coating layer according to the present disclosure will be described by comparing an Embodiment with Comparative Examples.

Table 1 below shows the measurement of modulus at low and high stresses, recovery rate, elongation, light transmittance, haze, and adhesion in the coating layers according to the Comparative Examples and the Embodiment. In this case, the modulus is defined as the Young's modulus of the sample in the strain range of 0.025% to 0.5% in the tensile evaluation. The recovery rate is defined as the yield strain in tensile evaluation and the recovery rate after cycle evaluation. The elongation is defined as the degree to which the specimen is stretched without breaking when tensioned with a constant force.

In Table 1, the coating layers of the Comparative Examples and the Embodiment were formed by dispersing nanoparticles in a proportion by weight of nanoparticles in the base layer. The base layers included in the coating layers of the Comparative Examples and the Embodiment were formed of an acrylic polymer, the nanoparticles were formed of silica, and the surfaces of the nanoparticles were formed by coating an acrylate polymer.

Specifically, the coating layer of the Comparative Example 1 does not include nanoparticles and is formed by including only a base layer. The coating layer of the Comparative Example 2 was formed by dispersing about 3 wt % of nanoparticles in the base layer. The coating layer of the Comparative Example 3 was formed by dispersing 5 wt % of nanoparticles in the base layer. The coating layer of the Embodiment was formed by dispersing 10 wt % of nanoparticles in the base layer. The coating layer of the Comparative Example 4 was formed by dispersing 15 wt % of nanoparticles in the base layer. The coating layer of the Comparative Example 5 was formed by dispersing 20 wt % of nanoparticles in the base layer.

TABLE 1

| | Weight | | | | | | | |
|---|---|---|---|---|---|---|---|---|
| | Ratio of | Modulus (MPa) | | | | Light | | |
| | Nano- | Low | | Recovery | Elong- | Trans- | | |
| | particle | Stress | High Stress | Rate | ation | mittance | Haze | Adhesion |
| | (wt %) | (0.1 Hz) | (1000 Hz) | (%) | (%) | (%) | (%) | (gf/inch) |
| Comparative | 0 | 0.04 | 0.08 | 97.4 | 170 | 96 | 0.31 | 1002 |
| Example 1 | | | | | | | | |
| Comparative | 3 | 0.13 | 7.5 | 97 | 173 | 97 | 0.4 | 1010 |
| Example 2 | | | | | | | | |
| Comparative | 5 | 0.47 | 21 | 95.1 | 161 | 96 | 0.48 | 994 |
| Example 3 | | | | | | | | |
| Embodiment | 10 | 0.83 | 63 | 93.8 | 153 | 92 | 0.80 | 990 |
| Comparative | 15 | 3.5 | 410 | 90.2 | 130 | 88 | 1.46 | 735 |
| Example 4 | | | | | | | | |
| Comparative | 20 | 8.8 | 730 | 88.7 | 108 | 84 | 1.83 | 600 |
| Example 5 | | | | | | | | |

Referring to Table 1, it may be seen that as the weight ratio of the nanoparticles in the coating layers of the Comparative Examples 1 to 5 and the Embodiment increases, both the modulus at low stress (e.g., 0.1 Hz) and the modulus in high stress (e.g., 1 kHz) increase. That is, it may be seen that as the weight ratio of the nanoparticles in the coating layer increases, the impact resistance of the coating layer is improved as the modulus increases.

In particular, it may be seen that the modulus at high stress (e.g., 1 kHz) increases more significantly than that at low stress (e.g., 0.1 Hz) as the weight ratio of the nanoparticles increases. Therefore, it may be seen that the coating layer of the Embodiment has significantly improved impact resistance compared to the coating layer of Comparative Example 1 because the numerical values are significantly different when comparing the coating layer according to the Embodiment with the coating layer according to the Comparative Example 1 in the modulus item at high stress. On the other hand, it may be seen that the foldability of the coating layer of the Embodiment is not significantly different from that of the coating layer in Comparative Example 1 because there is no significant difference between the coating layer of the Embodiment and the coating layer of Comparative Example 1 in the modulus item at low stress. That is, it may be seen that the foldability of the coating layer may be secured even when the weight ratio of the nanoparticles in the coating layer is about 10 wt %.

It may be seen that the recovery rate of the coating layers of the Comparative Examples 1 to 5 and the Embodiment decreases as the weight ratio of the nanoparticles increases. It may be seen that the elongation of the coating layers of the Comparative Examples 1 to 5 and the Embodiment generally decreases as the weight ratio of the nanoparticles increases. It may be seen that the transmittance of the coating layers of the Comparative Examples 1 to 5 and the Embodiment generally decreases as the weight ratio of the nanoparticles increases. It may be seen that the haze of the coating layers of the Comparative Examples 1 to 5 and the Embodiment increases as the weight ratio of the nanoparticles increases. It may be seen that the adhesion of the coating layers of the Comparative Examples 1 to 5 and the Embodiment generally decreases as the weight ratio of the nanoparticles increases.

Accordingly, it may be confirmed that as the weight ratio of the nanoparticles of the coating layer increases, the impact resistance of the coating layer is secured, but the foldability (folding easiness), the light transmittance, and the adhesion are lowered. Conversely, it may be seen that the smaller the weight ratio of the nanoparticles in the coating layer, the higher the foldability (folding easiness), the light transmittance, and the adhesion, but the lower the impact resistance of the coating layer. Accordingly, the display device including the coating layer of the Embodiment including about 10 wt % of nanoparticles in which the foldability, the light transmittance, and the adhesion of the coating layer are not significantly lowered while ensuring the impact resistance of the coating layer may exhibit the best characteristics.

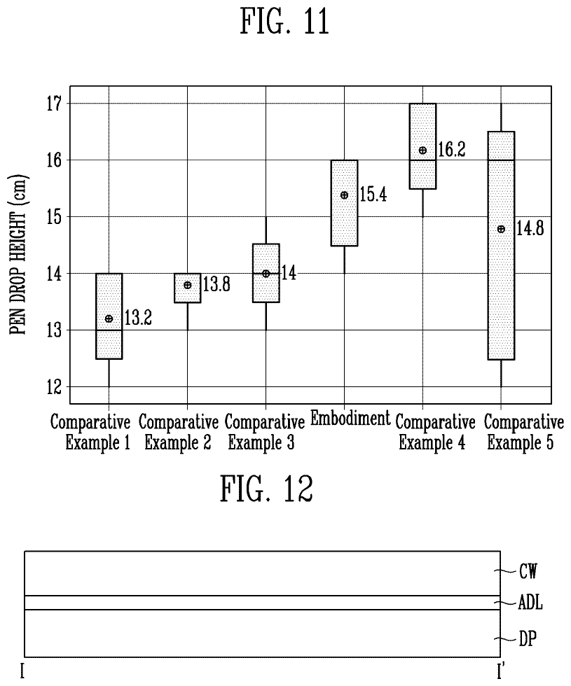

FIG. 11 is a graph illustrating a result of performing a pen drop test on a coating layer according to a comparative example and an embodiment. The pen drop test may be performed by dropping a pen over the coating layer. The impact resistance may be evaluated by measuring a drop height of the pen where damage occurs to the coating layer in the pen drop test. The higher the drop height of the pen, the better the impact resistance of the coating layer. In the graph of FIG. 11, a bar means a deviation of the drop height of the pen, and a dot means an average value of the drop height.

Referring to FIG. 11, except for the Comparative Example 5, in the coating layers of the Comparative Examples 1 to 4 and the Embodiment, as the weight ratio of the nanoparticles increases, the drop height of the pen increases, and thus it may be seen that the impact resistance is improved. In the case of the Comparative Example 5, since a large amount of nanoparticles are included, it may be seen that the nanoparticles are not uniformly dispersed due to agglomeration of the nanoparticles, and thus the deviation of the drop height of the pen is large.

Table 2 below shows the measurement of the impact absorption rate and the impact area in the coating layers according to the Comparative Example 1, the Comparative Example 4, and the Embodiment using a pressure-sensitive paper.

TABLE 2

| | Comparative | | Comparative |
|---|---|---|---|
| | Example 1 | Embodiment | Example 4 |
| Impact Absorption Rate | 23.1 | 26.5 | 30.2 |
| (%) | | | |
| Impact Area (μm²) | 831506 | 1128468 | 1171233 |

Referring to Table 2, it may be seen that the impact absorption rate of the coating layers of the Comparative Example 1, the Comparative Example 4, and the Embodiment increases as the weight ratio of the nanoparticles increases. Likewise, it may be seen that the coating layers of the Comparative Example 1, the Comparative Example 4, and the Embodiment have an increased impact area as the weight ratio of the nanoparticles increases. Through this, it may be seen that as the weight ratio of the nanoparticles in the coating layer increases, the impact absorption rate and the impact area increase, thereby improving the impact resistance of the coating layer.

In embodiments, by including nanoparticles in the coating layer, the coating layer may have the shear thickening property. Accordingly, the impact resistance of the coating layer may be improved. In addition, since the coating layer includes nanoparticles, which are greater than 5 wt % to less than 15 wt % of a total weight of the coating layer, the coating layer may not significantly deteriorate in the foldability, the light transmittance, and the adhesion while securing the impact resistance, and thus can secure the foldability, the light transmittance, and the adhesion at the same time as the impact resistance. Accordingly, while the coating layer prevents damage to the display panel, the reliability of the display device may be improved by securing the foldability and the light transmittance of the display device. In addition, since the coating layer has adhesive force, a separate adhesive layer may not be required, so that the structure of the display device may become simple, and the thickness of the display device may be reduced.

FIGS. 12 to 17 are views illustrating a method of manufacturing a display device according to an embodiment of the present disclosure. FIG. 15 is an enlarged view illustrating only the cover window and the coating layer of FIG. 14. For example, FIGS. 12 to 17 may illustrate a method of manufacturing the display device of FIG. 5. However, embodiments are not limited thereto.

Referring to FIG. 12, a display panel DP may be formed. The display panel DP may include the substrate SUB of FIG. 7, a pixel circuit layer PCL including a sub-pixel circuit SPC (see FIG. 2), a display element layer DPL including light-emitting elements, and a light functional layer LFL including light conversion patterns and a color filter layer.

A cover window CW may be formed on the display panel DP. The cover window CW may be attached on the display panel DP through the adhesive layer ADL.

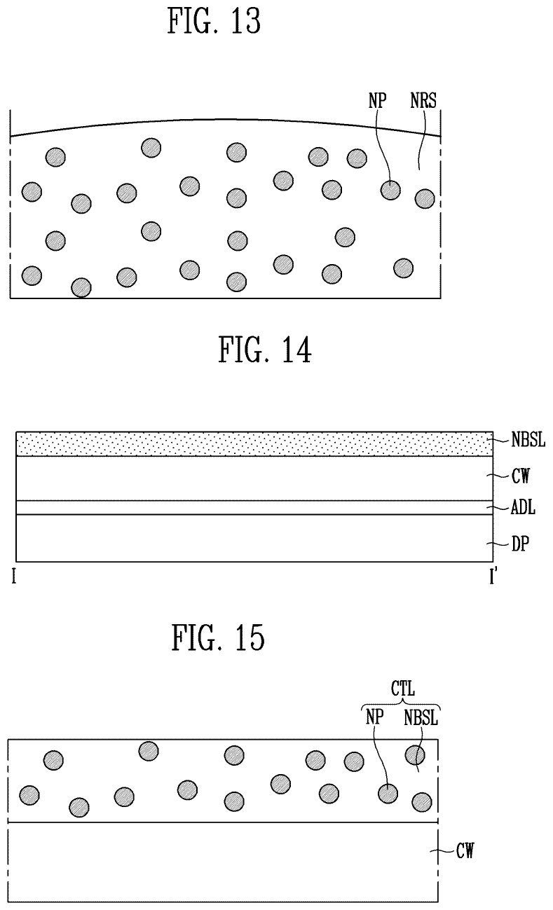

Referring to FIGS. 13 to 16, a coating layer CTL including nanoparticles NP, which are greater than 5 wt % to less than 15 wt % of a total weight of the coating layer CTL may be formed on the display panel DP.

Referring to FIG. 13, the nanoparticles NP, which are greater than 5 wt % to less than 15 wt % of the total weight of the coating layer CTL, may be dispersed in the uncured resin layer NRS. Since the uncured resin layer NRS is formed of an optically clear resin and is in a solution state, the nanoparticles NP may be easily dispersed in the uncured resin layer NRS.

In embodiments, each of the nanoparticles NP may include silica, which is an inorganic material. In other embodiments, each of the nanoparticles NP may include at least one of acrylic, styrene, or polymethylmethacrylate, which are organic materials.

In embodiments, the nanoparticles NP may be surface coated. That is, each of the nanoparticles NP may have a core-shell structure.

Referring to FIGS. 14 and 15, the uncured base layer NBSL in which the nanoparticles NP are dispersed may be formed on the cover window CW by applying the uncured resin layer NRS in which the nanoparticles NP are dispersed. The uncured resin layer NRS may be applied on the cover window CW by a jet dispensing method, an inkjet method, a slit coating method, or the like.

Referring to FIG. 16, the uncured base layer NBSL may be cured to form the base layer BSL. In this case, the uncured base layer NBSL may be cured by at least one of ultraviolet curing or low-temperature thermosetting. This may prevent damage to the display panel DP and other layers under the uncured base layer NBSL in the process of curing the uncured based layer NBSL.

In embodiments, since the base layer BSL includes the optically clear resin, the base layer BSR may have the transmittance and the adhesion.

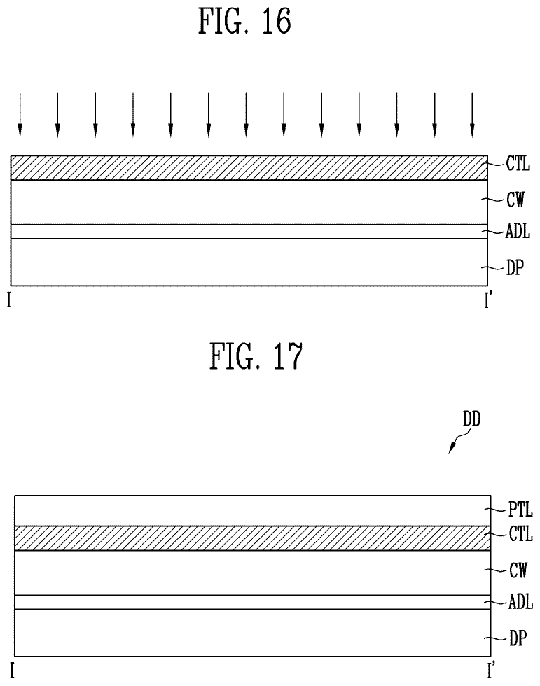

Referring to FIG. 17, a protective layer PTL may be formed on the coating layer CTL. Accordingly, the display device DD including the display panel DP, the adhesive layer ADL, the cover window CW, the coating layer CTL, and the protective layer PTL may be formed.

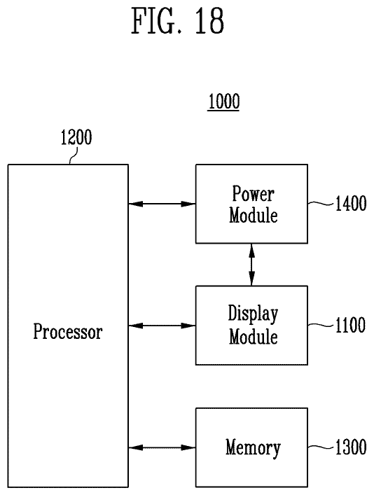

FIG. 18 is a block diagram of an electronic device according to an embodiment.

Referring to FIG. 18, an electronic device 1000 according to an embodiment may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

The memory 1300 may store data information necessary for an operation of the processor 1200 or the display module 1100. When the processor 1200 executes an application stored in the memory 1300, an image data signal and/or an input control signal may be transmitted to the display module 1100, and the display module 1100 may process the received signal and output image information through a display screen.

The power module 1400 may include a power supply module such as a power adapter or a battery device, and a power conversion module that converts power supplied by the power supply module to generate power for operation of the electronic device 1000.

At least one of the above-described components of the electronic device 1000 may be included in the display device DD according to the above-described embodiments. In addition, some of the individual modules functionally included in one module may be included in the display device, and other parts may be provided separately from the display device DD. For example, the display device DD may include the display module 1100, and the processor 1200, the memory 1300, and the power module 1400 may be provided in the form of other devices in the electronic device 1000 other than the display device DD.

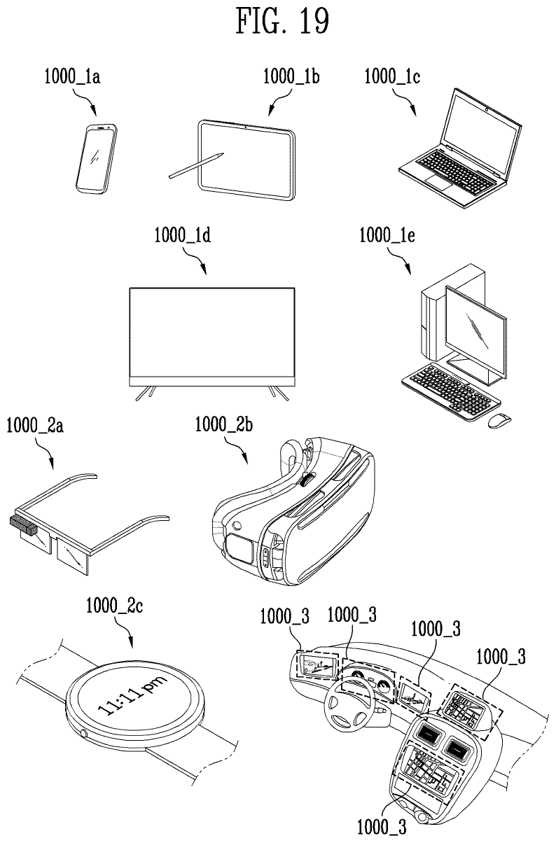

FIG. 19 is a schematic diagram of an electronic device according to various embodiments.

Referring to FIG. 19, various electronic devices to which a display device according to embodiments is applied may include not only an electronic device for displaying an image, such as a smartphone 1000_1a, a tablet PC 1000_1b, a laptop 1000_1c, a TV 1000_1d, and a desk monitor 1000_1e, but also a wearable electronic device including a display module, such as smart glasses 1000_2a, a head mounted display 1000_2b, and a smart watch 1000_2c, a vehicle electronic device 1000_3 including a display module such as a CID (Center Information Display) disposed on an instrument panel, a center fascia, and a dashboard of a vehicle, a room mirror display, and the like.

Although the technical spirit of the disclosure has been described in detail in accordance with the above-described embodiments, it should be noted that the above-described embodiments are for the purpose of description and not of limitation. Those skilled in the art can understand that various modifications are possible within the scope of the technical spirit of the disclosure.

The scope of the disclosure is not limited to the details described in the detailed description of the specification, but should be defined by the claims. It is to be construed that all changes or modifications derived from the meaning and scope of the claims and equivalent concepts thereof are included in the scope of the disclosure.

What is claimed is:

1. A display device comprising:
a display panel including a light-emitting element; and
a coating layer disposed on the display panel and including nanoparticles, which are greater than 5 weight percents (wt %) to less than 15 wt % of a total weight of the coating layer.

2. The display device of claim 1, wherein the coating layer includes a base layer in which the nanoparticles are dispersed.

3. The display device of claim 2, wherein the base layer includes an optically clear resin (OCR).

4. The display device of claim 3, wherein the base layer includes at least one of an acrylic polymer, a urethane polymer, or a silicone polymer.

5. The display device of claim 2, wherein each of the nanoparticles includes silica.

6. The display device of claim 2, wherein each of the nanoparticles includes at least one of acrylic, styrene, or polymethyl methacrylate (PMMA).

7. The display device of claim 2, wherein an elongation of the coating layer is equal to or greater than 150% and less than 161%.

8. The display device of claim 2, wherein a modulus of the coating layer at 0.1 Hz of stress is greater than 0.47 to less than 3.5 megapascal (MPa).

9. The display device of claim 2, wherein an adhesive force of the coating layer at room temperature is equal to or greater than 800 gram-force per inch (gf/inch) and less than 994 gf/inch.

10. The display device of claim 1, wherein a haze of the coating layer is greater than 0.48% and less than 1.46%.

11. The display device of claim 1, wherein the nanoparticles are surface-coated.

12. A method of manufacturing a display device, the method comprising:
forming a display panel including a light-emitting element; and
forming a coating layer including nanoparticles, which are greater than 5 wt % to less than 15 wt % of a total weight of the coating layer, on the display panel.

13. The method of claim 12, wherein the forming of the coating layer includes:
dispersing the nanoparticles in a resin solution;
applying the resin solution onto the display panel to form an uncured base layer; and
curing the uncured base layer to form a base layer.

14. The method of claim 13, wherein the uncured base layer is cured by at least one of an ultraviolet curing method or a low-temperature thermosetting method.

15. The method of claim 13, wherein the base layer includes an optically clear resin (OCR).

16. The method of claim 12, wherein each of the nanoparticles includes silica.

17. The method of claim 12, wherein each of the nanoparticles includes at least one of acrylic, styrene, or polymethyl methacrylate (PMMA).

18. An electronic device comprising:
a processor; and
a display device, which displays an image according to control of the processor,
wherein the display device includes:
a display panel including a light-emitting element; and
a coating layer disposed on the display panel and including nanoparticles, which are greater than 5 wt % to less than 15 wt % of a total weight of the coating layer.

19. The display device of claim 18, wherein the coating layer has a recovery rate greater 90.2% than to less than 95.1%.

20. The display device of claim 18, wherein a modulus of the coating layer at 1000 Hz of stress is greater than 21 to less than 410 MPa.
